(19) United States
(12) Patent Application Publication
(10) Pub. No.: US 2019/0067246 A1
(43) Pub. Date: Feb. 28, 2019

(54) SEMICONDUCTOR STRUCTURE AND METHOD FOR MANUFACTURING THE SAME

(71) Applicant: MACRONIX INTERNATIONAL CO., LTD., Hsinchu (TW)

(72) Inventors: Guan-Wei Wu, Kaohsiung City (TW); Chu-Yung Liu, Yuanlin City (TW); Yao-Wen Chang, Hsinchu City (TW); I-Chen Yang, Changhua City (TW)

(21) Appl. No.: 15/683,850

(22) Filed: Aug. 23, 2017

(51) Int. Cl. H01L 25/065; H01L 21/02; H01L 21/768

(52) U.S. Cl. CPC H01L 25/0657; H01L 21/02381; H01L 2225/06541; H01L 21/76877; H01L 21/02458; H01L 21/02505

(57) ABSTRACT

A semiconductor structure includes a substrate, a stack of alternate conductive layers and insulating layers, a hole, and an active structure. The stack is disposed on the substrate. The conductive layers include an i^{th} conductive layer and a j^{th} conductive layer disposed above the i^{th} conductive layer, the i^{th} conductive layer has a thickness tᵢ, the j^{th} conductive layer has a thickness tⱼ, and tⱼ is larger than tᵢ. The hole penetrates through the stack. The hole has a diameter Dᵢ and a diameter Dⱼ corresponding to the i^{th} conductive layer and the j^{th} conductive layer, respectively, and Dⱼ is larger than Dᵢ. The active structure is disposed in the hole. The active structure includes a channel layer. The channel layer is disposed along a sidewall of the hole and isolated from the conductive layers of the stack.

### TECHNICAL FIELD

This disclosure relates to a semiconductor structure and a method for manufacturing the same. More particularly, this disclosure relates to a semiconductor structure comprising a compensating stack structure and a method for manufacturing the same.

### BACKGROUND

For reasons of decreasing volume and weight, increasing power density, improving portability, and the like, three-dimensional (3D) semiconductor structures have been developed. In some typical manufacturing processes for 3D semiconductor structures, a stack comprising a plurality of layers may be formed on the substrate, and one or more holes and/or trenches then be formed through the stack. Due to the limitation of the manufacturing processes, the holes and/or trenches may have inclined sidewalls, and thereby sizes and areas gradually change along a vertical direction of the holes and/or trenches. This may further lead to some deviation in characteristics of the device, and particular the deviation in electrical characteristics. As the number of layers in the stack increases, the deviation may become a problem that will affect the performance and operation of the device.

### SUMMARY

The disclosure is directed to the provision of a compensating stack structure, which compensates the effect of the different sizes and areas along a vertical direction of the holes and/or the trenches.

According to some embodiments, a semiconductor structure is provided. The semiconductor structure comprises a substrate, a stack of alternate conductive layers and insulating layers, a hole, and an active structure. The stack is disposed on the substrate. The conductive layers comprise an i^{th} conductive layer and a j^{th} conductive layer disposed above the i^{th} conductive layer, the i^{th} conductive layer has a thickness tᵢ, the j^{th} conductive layer has a thickness tⱼ, and tⱼ is larger than tᵢ. The hole penetrates through the stack. The hole has a diameter Dᵢ and a diameter Dⱼ corresponding to the i^{th} conductive layer and the j^{th} conductive layer, respectively, and Dⱼ is larger than Dᵢ. The active structure is disposed in the hole. The active structure comprises a channel layer. The channel layer is disposed along a sidewall of the hole and isolated from the conductive layers of the stack.

According to some embodiments, a method for manufacturing a semiconductor structure is provided. The method comprises following steps. First, a stack of alternate sacrificial layers and insulating layers is formed on a substrate. The sacrificial layers comprise an i^{th} sacrificial layer and a j^{th} sacrificial layer formed above the i^{th} sacrificial layer, the i^{th} sacrificial layer has a thickness tᵢ, the j^{th} sacrificial layer has a thickness tᵢ, and tⱼ is larger than tᵢ. A hole is formed through the stack. The hole has a diameter Dᵢ and a diameter Dⱼ corresponding to the i^{th} sacrificial layer and the j^{th} sacrificial layer, respectively, and Dⱼ is larger than Dᵢ. An active structure is formed in the hole. The active structure comprises a channel layer. The channel layer is formed along a sidewall of the hole and separated from the sacrificial layers of the stack.

### BRIEF DESCRIPTION OF THE DRAWINGS

FIG. 1 shows an exemplary semiconductor structure according to embodiments.

FIG. 2 shows another exemplary semiconductor structure according to embodiments.

FIG. 3 shows the effect of diameters of a hole and the effect of channel lengths in one aspect.

FIGS. 4A-4B show the effect of diameters of a hole in another aspect.

FIGS. 5A-5H show an exemplary method for manufacturing a semiconductor structure according to embodiments.

In the following detailed description, for purposes of explanation, numerous specific details are set forth in order to provide a thorough understanding of the disclosed embodiments. It will be apparent, however, that one or more embodiments may be practiced without these specific details. In other instances, well-known structures and devices are schematically shown in order to simplify the drawing.

### DETAILED DESCRIPTION

Various embodiments will be described more fully hereinafter with reference to accompanying drawings. The accompanying drawings are provided for illustrative and explaining purposes rather than a limiting purpose. For clarity, the elements may not be drawn to scale. In addition, some components and/or reference numerals may be omitted from some drawings. In this disclosure, when a singular form is used to illustrate an element, the conditions of including more than one of the elements are also allowed. It is contemplated that the elements and features of one embodiment can be beneficially incorporated in another embodiment without further recitation.

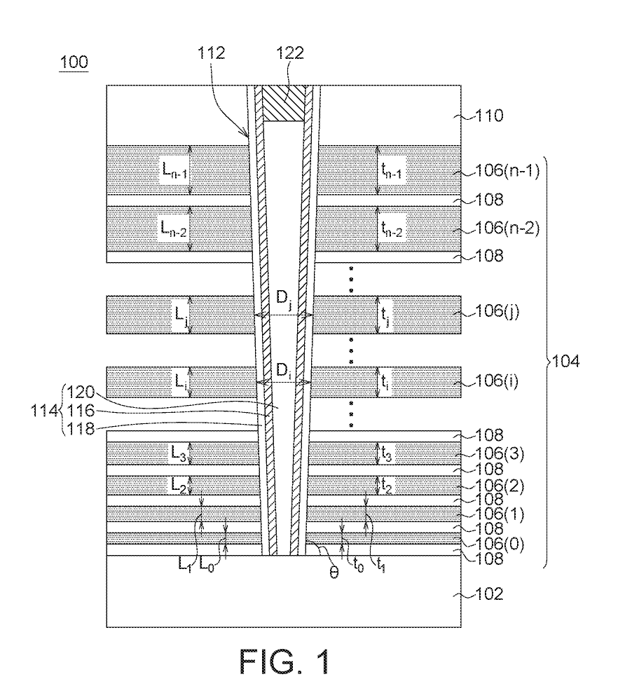

Referring to FIG. 1, an exemplary semiconductor structure 100 according to embodiments is shown. The semiconductor structure 100 comprises a substrate 102, a stack 104 of alternate conductive layers 106 (106(0) to 106(n−1)) and insulating layers 108, a hole 112, and an active structure 114. The stack 104 is disposed on the substrate 102. The conductive layers 106 comprise an i^{th} conductive layer 106(i) and a j^{th} conductive layer 106(j) disposed above the i^{th} conductive layer 106(i), the i^{th} conductive layer 106(i) has a thickness tᵢ, the j^{th} conductive layer 106(j) has a thickness tⱼ, and tⱼ is larger than tᵢ. The hole 112 penetrates through the stack 104. The hole 112 has a diameter Dᵢ and a diameter Dⱼ corresponding to the i^{th} conductive layer 106(i) and the j^{th} conductive layer 106(j), respectively, and Dⱼ is larger than Dᵢ. The active structure 114 is disposed in the hole 112. The active structure 114 comprises a channel layer 116. The channel layer 116 is disposed along a sidewall of the hole 112 and isolated from the conductive layers 106 of the stack 104.

In some embodiments, the stack 104 is disposed on the substrate 102, a cap layer 110 is further disposed on the stack 104, and the hole 112 penetrates through the cap layer 110 and the stack 104. In some embodiments, an angle θ between the substrate 102 and the sidewall of the hole 112 is smaller than 90°, such as about 87°. The hole 112 may have gradually larger diameters from bottom to top. In some embodiments, the diameters of the hole 112 are between 80 nm and 130 nm. For example, the hole 112 may have a diameter of 80 nm at the bottom, and have a diameter of 130 nm at the top. Correspondingly, the conductive layers 106 may have gradually thicker thicknesses from bottom to top, the details of which will be described in the following paragraphs. In some embodiments, the conductive layers 106 may comprise a metal material and a high-k material. According to some embodiments, the semiconductor structure 100 may be a memory structure. In such embodiments, the active structure 114 may further comprise a memory layer 118. The memory layer 118 is disposed between the channel layer 116 and the stack 104. The memory layer 118 may comprise a trapping layer (not shown). More specifically, in some embodiments, the memory layer 118 may comprise a barrier layer (not shown), a trapping layer (not shown), and a tunneling layer (not shown) disposed sequentially from the sidewall of the hole 112, and be formed of an oxide-nitride-oxide (ONO) stack. Memory cells constituting a portion of a 3D cell array are defined by cross points between the active structure 114 and the conductive layers 106 of the stack 104. In some embodiments, the active structure 114 may further comprise an insulating material 120. The insulating material 120 is filled into the remaining space of the hole 112. In some embodiments, a conductive component 122 may be disposed on the insulating material 120. In some embodiments, the conductive layers 106 are word lines, and the active structure 114 is coupled to a bit line through the conductive component 122.

Now the description is directed to the details of the arrangement of the conductive layers 106. Specifically, the conductive layers 106 may be a 0^{th} conductive layer 106(0) to a (n−1)^{th} conductive layer 106(n−1) from bottom to top. The 0^{th} conductive layer 106(0) to the (n−1)^{th} conductive layer 106(n−1) have thicknesses t₀ to tₙ₋₁, respectively, and t₀≤t₁≤ . . . ≤tₙ₋₂≤tₙ₋₁. In addition, the 0^{th} conductive layer 106(0) to the (n−1)^{th} conductive layer 106(n−1) can provide channel lengths L₀ to Lₙ₋₁, respectively, and L₀≤L₁≤ . . . ≤Lₙ₋₂≤Lₙ₋₁. According to some embodiments, the channel lengths L₀ to Lₙ₋₁ are defined in a vertical direction, which indicates a direction substantially perpendicular to the substrate 102 throughout the disclosure. Thereby, each channel length (L₀ to Lₙ₋₁) is substantially equal to the corresponding thickness (t₀ to tₙ₋₁). In some embodiments, the thicknesses t₀ to tₙ₋₁ and thereby the channel lengths L₀ to Lₙ₋₁ are between 20 nm and 60 nm. For example, the thickness to and the channel lengths L₀ may be 20 nm, and the thickness tₙ₋₁ and the channel lengths Lₙ₋₁ may be 60 nm.

As long as the compensating function can be provided such that the deviation is in an acceptable range, the thicknesses t₀ to tₙ₋₁ and thereby the channel lengths L₀ to Lₙ₋₁ can be arranged in any suitable manner. In some embodiments, as shown in FIG. 1, each of the conductive layers 106 is thicker than the conductive layers 106 under said each of the conductive layers 106. In other words, t₀<₁< . . . <tₙ₋₂<tₙ₋₁. In other words, L₀<L₁< . . . <Lₙ₋₂<Lₙ₋₁.

In some other embodiments, the conductive layers 106 are divided into a plurality of groups, and the conductive layers 106 in each of the groups have the same thickness and are thicker than the conductive layers 106 in the groups under said each of the groups. In such embodiments, for at least one i being an integer from 0 to n−2, tᵢ=tᵢ₊₁. In other words, for at least one i being an integer from 0 to n−2, Lᵢ=Lᵢ₊₁.

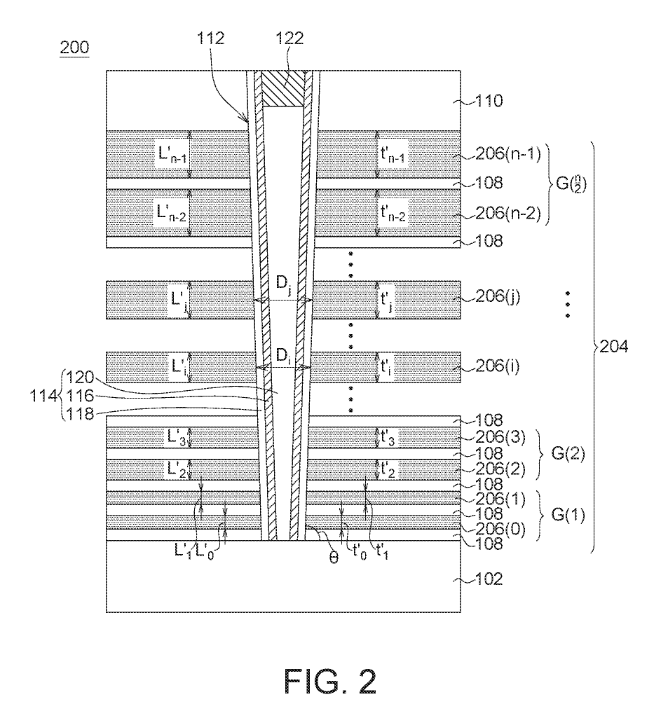

Referring to FIG. 2, a particular type of such embodiments is shown. In this particular type, the conductive layers 106 are equally divided into a plurality of groups, and the conductive layers 106 in each of the groups have the same thickness and are thicker than the conductive layers 106 in the groups under said each of the groups. For example, the conductive layers 106 can be equally divided into

$$\frac{n}{m}$$

groups, i.e., each of the groups comprises m conductive layers, and t′₀=t′₁= . . . =t′ₘ₋₁<t′ₘ . . . <t′ₙ₋ₘ= . . . =t′ₙ₋₂=t′ₙ₋₁. In other words, the conductive layers 106 can be equally divided into

$$\frac{n}{m}$$

groups, and L′₀=L′₁= . . . =L′ₘ₋₁< . . . <L′ₙ₋ₘ= . . . =L′ₙ₋₂=L′ₙ₋₁. In the semiconductor structure 200 shown in FIG. 2, m is 2. In other words, in the stack 204, the conductive layers 206(0) to 206(n−1) are equally divided into

$$\frac{n}{2}$$

groups G(1) to

$$\frac{n}{G ( 2 )} ,$$

each of the groups G(1) to

$$\frac{n}{G ( 2 )}$$

comprises two of the conductive layers 206(0) to 206(n−1), t′₀=t′₁<t′₂=t′₃< . . . <t′ₙ₋₂=t′ₙ₋₁, and L′₀=L′₁<L′₂=L′₃< . . . <L′ₙ₋₂=L′ₙ₋₁.

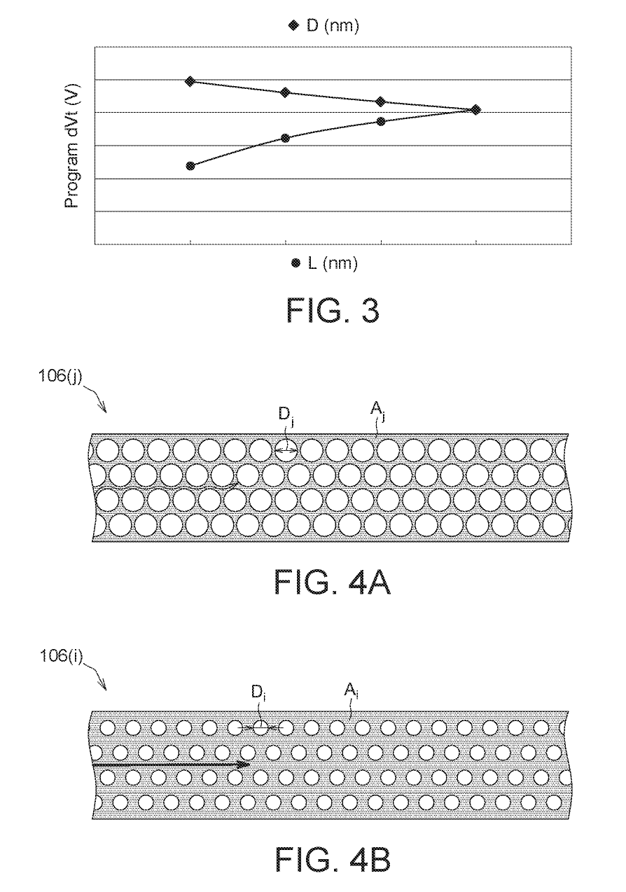

The stack according to the embodiments described above, such as the stack 104 or 204, is referred to as a compensating stack structure in this disclosure. In one aspect, a larger diameter of the hole means a smaller electrical field, and thereby a lower program/erase speed and a worse program/erase capability. This is reflected by the tendency shown in FIG. 3. In contrast, a larger channel length leads to a larger electrical field, and thereby a higher program/erase speed and a better program/erase capability. As such, in the semiconductor structure according to the embodiments, the effect of a larger diameter of the hole on program/erase operation of the device can be compensated by a larger channel length, which is achieved by a thicker conductive layer. Thereby, a better program/erase stability can be provided.

In addition, a larger diameter of the hole means a smaller conductive area for the corresponding conductive layer, and thereby a reduction in the conductance. For example, as shown in FIGS. 4A and 4B, the hole 112 has a larger diameter Dᵢ corresponding to the conductive layer 106(j). As such, the conductive area Aⱼ of the conductive layer 106(j) is smaller than the conductive area Aᵢ of the conductive layer 106(i). This is disadvantageous for the current passage in the conductive layer disposed at a higher level (i.e., a higher position), as indicated by the arrow in FIGS. 4A and 4B. For example, in the cases that the conductive layers are word lines, degradation on word line resistance may be occurred. However, such condition can be compensated by the thickness of the conductive layer. In other words, the effect of a larger diameter of the hole on the conductance of the conductive layers can be compensated by a thicker thickness of the conductive layers.

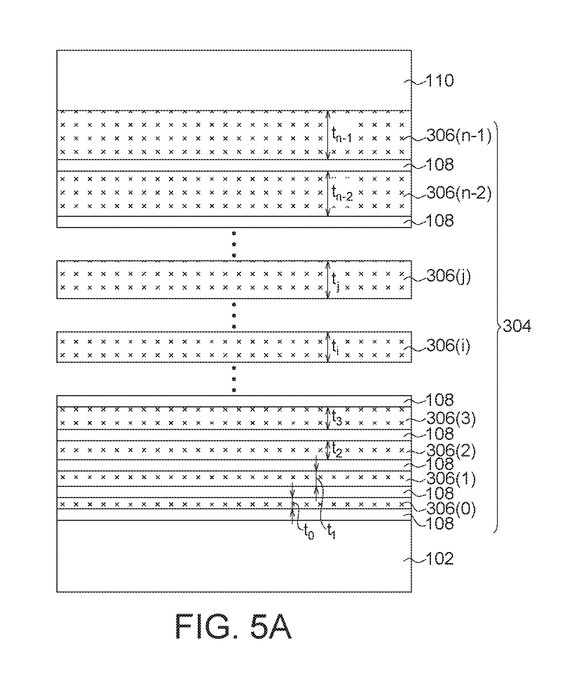

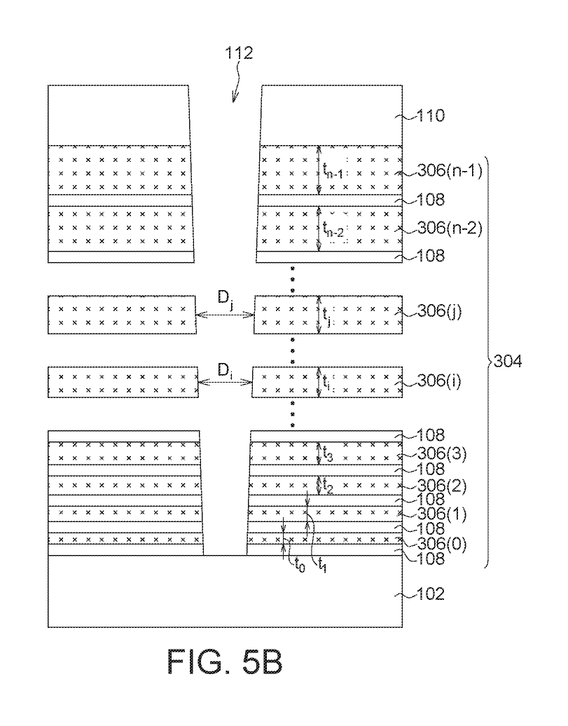

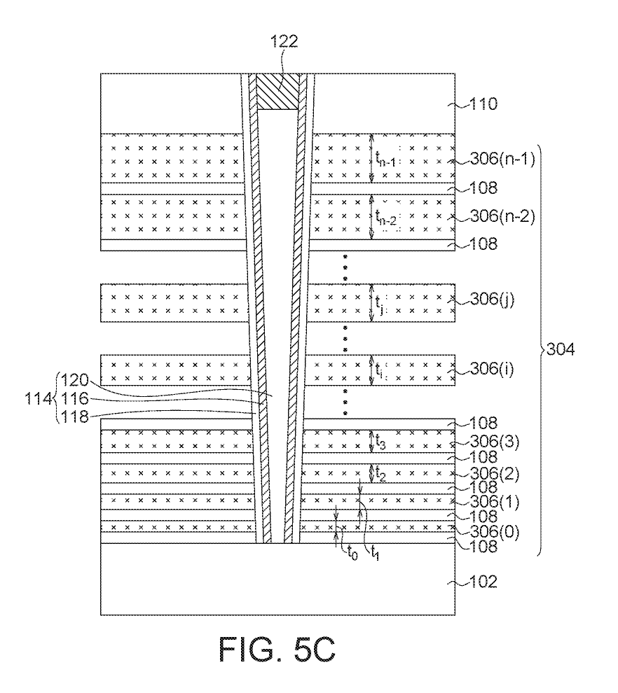

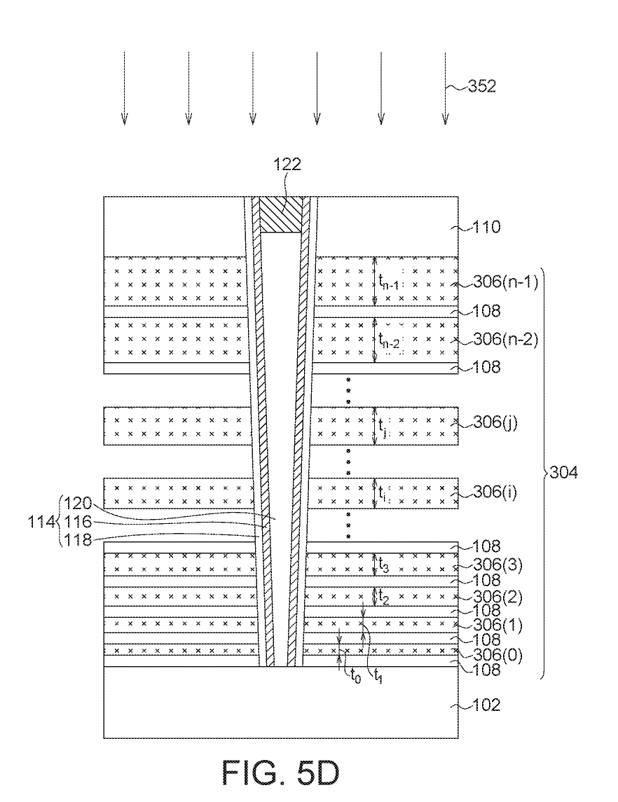

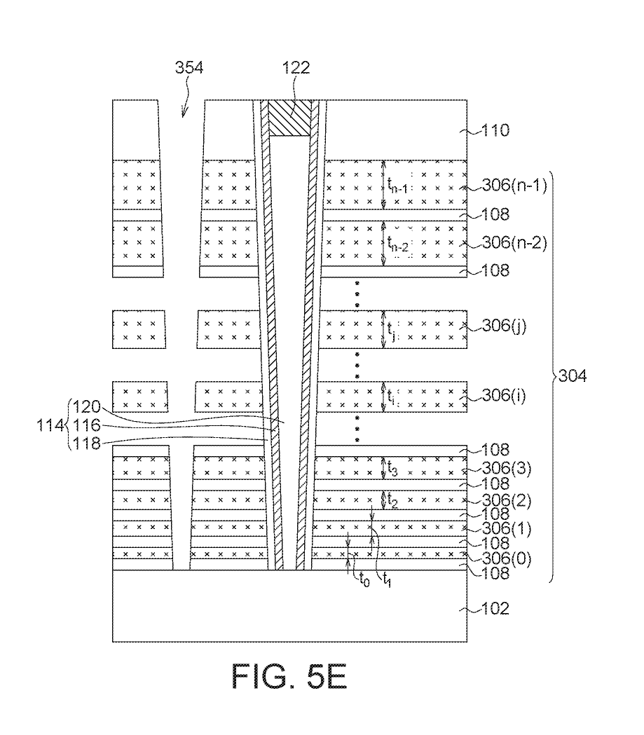

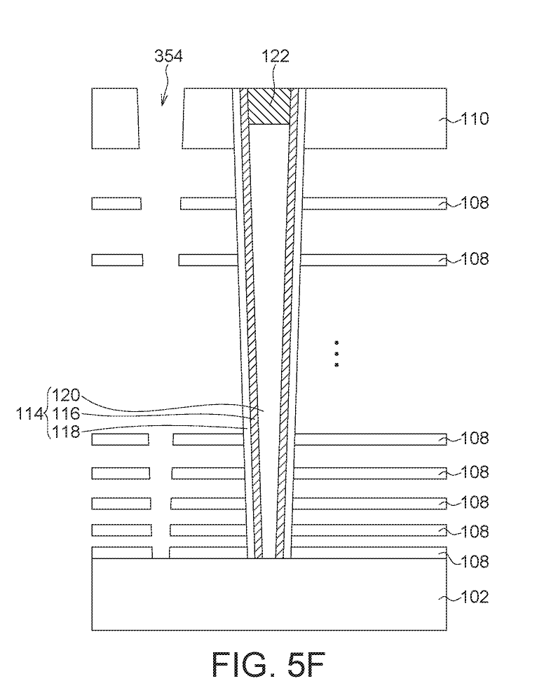

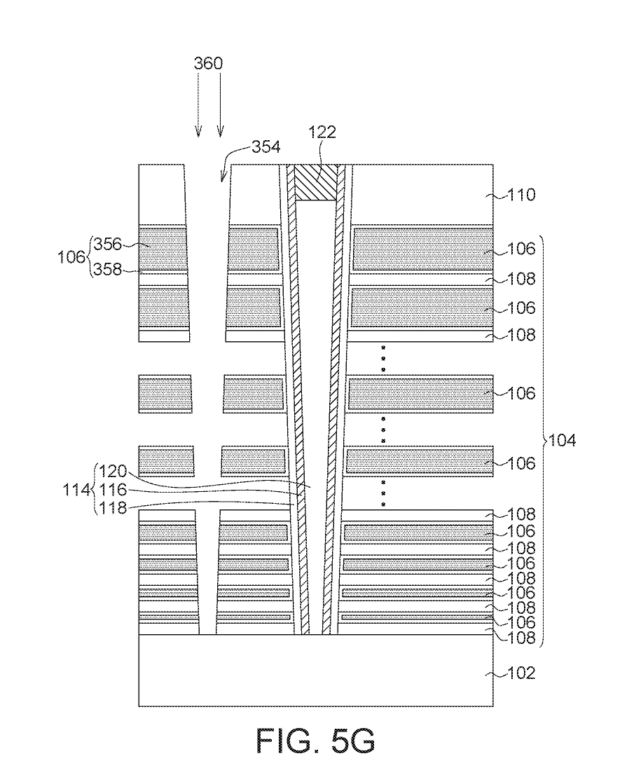

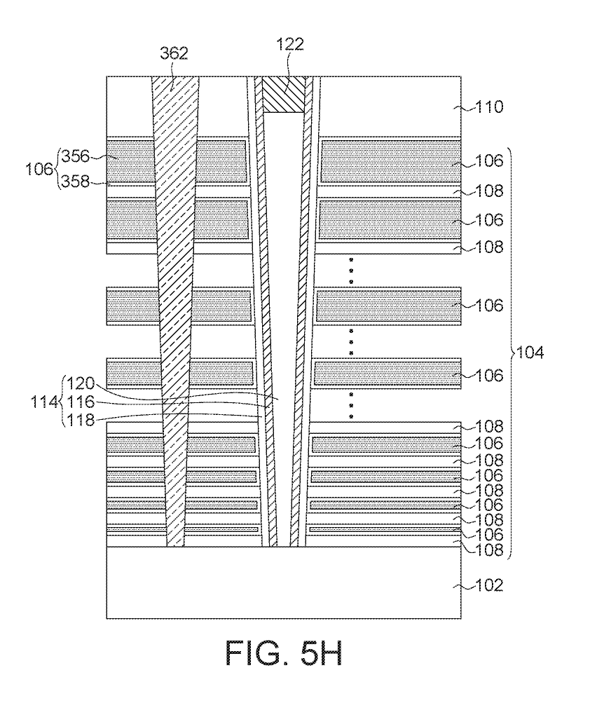

Now referring to FIGS. 5A-5H, an exemplary method for manufacturing a semiconductor structure according to embodiments is shown. FIGS. 5A-5H illustrate the formation of a semiconductor structure as shown in FIG. 1 by a sacrificial layer replacement process. However, other processes can also be used to form a semiconductor structure according to embodiments. For example, a stack of alternative conductive layers and insulating layers can be directly formed without sacrificial layers. In addition, other semiconductor structures according to embodiments, such as the semiconductor structure shown in FIG. 2, can also be formed.

As shown in FIG. 5A, a substrate 102 is provided. The substrate 102 may be a silicon substrate. An ion implantation process may be conducted. A stack 304 of alternate sacrificial layers (306(0) to 306(n−1)) and insulating layers 108 is formed on the substrate 102, such as by a deposition process. The insulating layers 108 may be formed of oxide with the same thickness. The sacrificial layers 306(0) to 306(n−1) may be formed of nitride. The sacrificial layers 306(0) to 306(n−1) comprise an i^{th} sacrificial layer 306(i) and a j^{th} sacrificial layer 306(j) formed above the i^{1h} sacrificial layer 306(i), the i^{th} sacrificial layer 306(i) has a thickness tᵢ, the j^{th} sacrificial layer 306(j) has a thickness tⱼ, and tⱼ is larger than tᵢ. More specifically, the sacrificial layers 306(0) to 306(n−1) may have thicknesses t₀ to tₙ₋₁, respectively, and t₀≤t₁≤ . . . ≤tₙ₋₂≤tₙ₋₁. In FIG. 5A, the sacrificial layers 306(0) to 306(n−1) are illustrated such that each of the sacrificial layers 306(0) to 306(n−1) is thicker than the sacrificial layers under said each of the sacrificial layers 306(0) to 306(n−1), i.e., t₀<t₁< . . . <tₙ₋₂<tₙ₋₁. However, in some other embodiments, the sacrificial layers 306(0) to 306(n−1) may have thicknesses gradually changing by groups. In such embodiments, for at least one i being an integer from 0 to n−2, tᵢ=tᵢ₊₁. For example, the sacrificial layers can be equally divided into

$$\frac{n}{m}$$

groups, i.e., each of the groups comprises m sacrificial layers, and t₀=t₁= . . . =tₘ₋₁<tₘ . . . <tₙ₋ₘ= . . . =tₙ₋₂=tₙ₋₁. In some embodiments, the thicknesses t₀ to tₙ₋₁, are between 20 nm and 60 nm. For example, the thickness to may be 20 nm, and the thickness tₙ₋₁ may be 60 nm. In some embodiments, a cap layer 110 may be formed on the stack 304. The cap layer 110 may be formed of oxide.

As shown in FIG. 5B, a hole 112 is formed through the stack 304, such as by an etching process. For example, the hole 112 may have a sidewall inclined by an angle of about 87°. The hole 112 has a diameter Dᵢ and a diameter Dⱼ corresponding to the i^{th} sacrificial layer 306(i) and the j^{th} sacrificial layer 306(j), respectively, and Dⱼ is larger than Dᵢ. In some embodiments, the diameters of the hole 112 are between 80 nm and 130 nm. For example, the hole 112 may have a diameter of 80 nm at the bottom, and have a diameter of 130 nm at the top.

As shown in FIG. 5C, an active structure 114 is formed in the hole 112. The active structure 114 comprises a channel layer 116. The channel layer 116 is formed along the sidewall of the hole 112 and separated from the sacrificial layers 306(0) to 306(n−1) of the stack 304. The channel layer 116 can be isolated from the stack 304 by any suitable insulating material. In some embodiments, a memory layer 118 provides the isolation function. The memory layer 118 may comprise a trapping layer (not shown). More specifically, in some embodiments, the memory layer 118 may comprise a barrier layer (not shown), a trapping layer (not shown), and a tunneling layer (not shown) disposed sequentially from the sidewall of the hole 112, and be formed of an oxide-nitride-oxide (ONO) stack. According to some embodiments, the active structure 114 may be formed by firstly forming an ONO stack (i.e., memory layer 118) on the sidewall of the hole 112. Then, a polysilicon layer is formed thereon as the channel layer 116. An insulating material 120, such as oxide, may be filled into remaining space of the hole 112. As such, a gate-all-around structure is formed. In some embodiments, a conductive component 122 may be further formed on the insulating material 120. Then, as shown in FIG. 5D, an ion implantation process 352 may be conducted for the provision of the connection to a bit line. The dopant may be arsenic.

Then, the sacrificial layers 306(0) to 306(n−1) are replaced with conductive layers 106. As shown in FIG. 5E, an opening 354 is formed through the stack 304, such as by an etching process. As shown in FIG. 5F, the sacrificial layers 306(0) to 306(n−1) are removed through the opening 354, such as by an etching process. Then, the conductive layers 106 are formed. According to some embodiments, the conductive layers 106 may comprise a metal material 356 and a high-k material 358. As shown in FIG. 5G, in some embodiments, the high-k material 358 may be formed on top sides and bottom sides of the insulating layers 108. The high high-k material 358 may further be formed around the active structure 114. The high-k material 358 may be Al₂O₃. Then, the metal material 356 is filled into remaining portions of spaces produced by removing the sacrificial layers 306(0) to 306(n−1). The metal material 356 may be tungsten. In some embodiments, word lines are thereby provided.

In some embodiments, the opening 354 is provided for a source region of the semiconductor structure, and an ion implantation process 360 may be conducted for the formation of the source region. The dopant may be arsenic. Then, as shown in FIG. 5H, a conductive component 362 (i.e., source conductive component) can be formed in the opening 354.

It will be apparent to those skilled in the art that various modifications and variations can be made to the disclosed embodiments. It is intended that the specification and examples be considered as exemplary only, with a true scope of the disclosure being indicated by the following claims and their equivalents.

1. A semiconductor structure, comprising:
a substrate;
a stack of alternate conductive layers and insulating layers disposed on the substrate, wherein the conductive layers comprise an i^{th} conductive layer and a j^{th} conductive layer disposed above the i^{th} conductive layer, the i^{th} conductive layer has a thickness tᵢ, the j^{th} conductive layer has a thickness tⱼ, and tⱼ is larger than tᵢ;
a hole penetrating through the stack, wherein the hole has a diameter Dᵢ and a diameter Dⱼ corresponding to the i^{th} conductive layer and the j^{th} conductive layer, respectively, and Dⱼ is larger than Dᵢ; and
an active structure disposed in the hole, the active structure comprising:
a channel layer disposed along a sidewall of the hole and isolated from the conductive layers of the stack.

2. The semiconductor structure according to claim 1, wherein the hole has gradually larger diameters from bottom to top, and the conductive layers have gradually thicker thicknesses from bottom to top.

3. The semiconductor structure according to claim 2, wherein each of the conductive layers is thicker than the conductive layers under said each of the conductive layers.

4. The semiconductor structure according to claim 2, wherein the conductive layers are divided into a plurality of groups, and the conductive layers in each of the groups have the same thickness and are thicker than the conductive layers in the groups under said each of the groups.

5. The semiconductor structure according to claim 2, wherein the conductive layers are equally divided into a plurality of groups, and the conductive layers in each of the groups have the same thickness and are thicker than the conductive layers in the groups under said each of the groups.

6. The semiconductor structure according to claim 1, wherein the conductive layers are a 0^{th} conductive layer to a (n−1)^{th} conductive layer from bottom to top, the 0^{th} conductive layer to the (n−1)^{th} conductive layer have thicknesses t₀ to tₙ₋₁, respectively, and t₀≤t₁≤ . . . ≤tₙ₋₂≤tₙ₋₁.

7. The semiconductor structure according to claim 6, wherein t₀<t₁< . . . <tₙ₋₂<tₙ₋₁.

8. The semiconductor structure according to claim 6, wherein, for at least one i being an integer from 0 to n−2, tᵢ=tᵢ₊₁.

9. The semiconductor structure according to claim 6, wherein the conductive layers are equally divided into
$$\frac{n}{m}$$
groups, and t₀=t₁= . . . =tₘ₋₁<tₘ . . . <tₙ₋ₘ= . . . =tₙ₋₂=tₙ₋₁.

10. The semiconductor structure according to claim 1, wherein the conductive layers are a 0^{th} conductive layer to a (n−1)^{th} conductive layer from bottom to top, the 0^{th} conductive layer to the (n−1)^{th} conductive layer provide channel lengths L₀ to Lₙ₋₁, respectively, and L₀≤L₁≤ . . . ≤Lₙ₋₂<Lₙ₋₁.

11. The semiconductor structure according to claim 10, wherein L₀<L₁< . . . <Lₙ₋₂<Lₙ₋₁.

12. The semiconductor structure according to claim 10, wherein, for at least one i being an integer from 0 to n−2, Lᵢ=Lᵢ₊₁.

13. The semiconductor structure according to claim 10, wherein the conductive layers are equally divided into
$$\frac{n}{m}$$
groups, and L₀=L₁= . . . =Lₘ₋₁< . . . <Lₙ₋ₘ= . . . =Lₙ₋₂=Lₙ₋₁.

14. The semiconductor structure according to claim 1, wherein an angle between the substrate and the sidewall of the hole is smaller than 90°.

15. The semiconductor structure according to claim 1, wherein the conductive layers comprise a metal material and a high-k material.

16. The semiconductor structure according to claim 1, wherein the active structure further comprises:
a memory layer disposed between the channel layer and the stack, wherein memory cells constituting a portion of a 3D cell array are defined by cross points between the active structure and the conductive layers of the stack.

17. The semiconductor structure according to claim 16, wherein the conductive layers are word lines, and the active structure is coupled to a bit line.

18. A method for manufacturing a semiconductor structure, comprising:
forming a stack of alternate sacrificial layers and insulating layers on a substrate, wherein the sacrificial layers comprise an i^{th} sacrificial layer and a j^{th} sacrificial layer formed above the i^{th} sacrificial layer, the i^{th} sacrificial layer has a thickness tᵢ, the j^{th} sacrificial layer has a thickness tⱼ, and tⱼ is larger than tᵢ;
forming a hole through the stack, wherein the hole has a diameter Dᵢ and a diameter Dⱼ corresponding to the i^{th} sacrificial layer and the j^{th} sacrificial layer, respectively, and Dⱼ is larger than Dᵢ; and
forming an active structure in the hole, the active structure comprising:
a channel layer formed along a sidewall of the hole and separated from the sacrificial layers of the stack.

19. The method according to claim 18, further comprising:
replacing the sacrificial layers with conductive layers.

20. The method according to claim 19, wherein replacing the sacrificial layers with the conductive layers comprises:
forming an opening through the stack;
removing the sacrificial layers through the opening;
forming a high-k material on top sides and bottom sides of the insulating layers and around the active structure; and
filling a metal material into remaining portions of spaces produced by removing the sacrificial layers.
